(19) United States
(12) Patent Application Publication
(10) Pub. No.: US 2013/0118548 A1
(43) Pub. Date: May 16, 2013

(54) APPARATUS AND METHODS FOR ENHANCING PHOTOVOLTAIC EFFICIENCY

(71) Applicants: Sandeep K. Giri, Mountain View, CA (US); Sijin Han, Milpitas, CA (US)

(72) Inventors: Sandeep K. Giri, Mountain View, CA (US); Sijin Han, Milpitas, CA (US)

(73) Assignee: QUALCOMM MEMS Technologies, Inc., San Diego, CA (US)

(21) Appl. No.: 13/294,961

(22) Filed: Nov. 11, 2011

(51) Int. Cl. H01L 31/052; H01L 31/18

(52) U.S. Cl. 136/246; 438/65; 257/E31.13

(57) ABSTRACT

This disclosure provides photovoltaic modules and methods of making the same. In one implementation, a photovoltaic module includes a plurality of photovoltaic devices configured to absorb light and generate electrical power and a plurality of conductors disposed over the photovoltaic devices. The photovoltaic module further includes a glass layer disposed over the photovoltaic devices, and the glass layer includes a textured surface opposite the plurality of photovoltaic devices. The textured surface includes features configured to diffract light incident the photovoltaic module. The photovoltaic module further includes a diffusive layer disposed over at least a portion of the plurality of conductors.

### TECHNICAL FIELD

This disclosure relates to photovoltaic devices and modules.

### DESCRIPTION OF THE RELATED TECHNOLOGY

For over a century fossil fuels such as coal, oil, and natural gas have provided the main source of energy in the United States. The need for alternative sources of energy is increasing. Fossil fuels are a non-renewable source of energy that is depleting rapidly. The large scale industrialization of developing nations such as India and China has placed a considerable burden on available fossil fuel. In addition, geopolitical issues can quickly affect the supply of such fuel. Global warming is also of greater concern in recent years. A number of factors are thought to contribute to global warming; however, widespread use of fossil fuels is presumed to be a major contributor to global warming. Thus, there is a need to find a renewable and economically viable source of energy that is also environmentally safe. Solar energy is an environmentally safe renewable source of energy that can be converted into other forms of energy such as heat and electricity.

Photovoltaic cells convert optical energy to electrical energy and thus can be used to convert solar energy into electrical power. Photovoltaic cells can be made very thin and modular, and can range in size from about a few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Additionally, photovoltaic cells can be used in a wide range of applications, such as providing power to satellites and other spacecraft, providing electricity to residential and commercial properties, charging automobile batteries, and powering mobile devices, such as smart phones or personal computers.

While photovoltaic devices have the potential to reduce reliance upon hydrocarbon fuels, the widespread use of photovoltaic devices has been hindered by a variety of factors, including energy inefficiency. Accordingly, there is a need for photovoltaic devices and modules having improved efficiency.

### SUMMARY

The systems, methods and devices of the disclosure each have several innovative aspects, no single one of which is solely responsible for the desirable attributes disclosed herein.

In one innovative implementation, a photovoltaic module includes a plurality of photovoltaic devices configured to absorb light and generate electrical power, a plurality of conductors disposed over the plurality of photovoltaic devices and configured to provide electrical connectivity within the photovoltaic module, a glass layer disposed over the plurality of conductors and the photovoltaic devices, the glass layer including a first textured surface opposite the plurality of photovoltaic devices. The first textured surface includes a plurality of features configured to diffract light incident the photovoltaic module; and a diffusive layer disposed over at least a portion of the plurality of conductors, the diffusive layer configured to diffract light. Each of the plurality of features of the first textured surface can have a width in the range of about 10 μm to about 100 μm. The photovoltaic module can further include an encapsulation layer disposed between the glass layer and the plurality of photovoltaic devices, the glass layer further including a second textured surface opposite the first textured surface, and the second textured surface including a plurality of features configured to improve the adhesion of the encapsulation layer to the glass layer. The feature width of the second textured surface can be greater than a feature width of the first textured surface. Each of the plurality of features of the second textured surface can have a width in the range of about 1 mm to about 10 mm. The diffusive layer can include at least one of titanium dioxide (TiO₂), polyethylene, polytetrafluoroethylene (PTFE), barium sulfate (BaSO₄), and white paint. The diffusive layer can be further disposed between the plurality of photovoltaic devices. The plurality of conductors can include a plurality of secondary conductive lines for collecting a photocurrent generated by the plurality of photovoltaic devices, and the diffusive layer can be disposed over at least a portion of the plurality of secondary conductive lines. The diffusive layer can be a Lambertian diffuser. In one aspect, the diffusive layer can include a film. In another aspect, the plurality of features of the first textured surface are arranged in a non-uniform pattern.

In another innovative aspect of the subject matter, a photovoltaic module includes a plurality of photovoltaic devices configured to absorb light and generate electrical power, a plurality of conductors disposed over the plurality of photovoltaic devices and configured to provide electrical connectivity within the photovoltaic module, and a means for diffusing light disposed over at least a portion of the plurality of conductors. Some implementations can further include a glass layer disposed over the plurality of conductors and the photovoltaic devices, the glass layer including a first textured surface opposite the plurality of photovoltaic devices, the first textured surface including a plurality of features configured to diffract light incident on the plurality of features. In one aspect, each of the plurality of features of the first textured surface has a width in the range of about 10 μm to about 100 μm. The photovoltaic module can further include an encapsulation layer disposed between the glass layer and the plurality of photovoltaic devices, the glass layer further including a second textured surface opposite the first textured surface, the second textured surface including a plurality of features configured to improve the adhesion of the encapsulation layer to the glass layer. Each of the plurality of features of the first textured surface can have a width in the range of about 1 mm to about 10 mm. In one aspect, at least a portion of the diffusive layer is applied between the photovoltaic devices. In another aspect, the diffusive layer includes at least one of titanium dioxide (TiO₂), polyethylene, polytetrafluoroethylene (PTFE), barium sulfate (BaSO₄), and white paint.

Another innovative implementation includes a method of manufacturing a photovoltaic module, the method including providing a plurality of photovoltaic devices configured to absorb light and generate electrical power, forming a plurality of conductors over the plurality of photovoltaic devices, providing a glass layer over the photovoltaic devices, the glass layer including a first textured surface opposite the plurality of photovoltaic devices, and forming a diffusive layer over at least a portion of the plurality of conductors, the diffusive layer configured to diffract light. The method can further include a second textured surface opposite the first textured surface, and wherein the method further comprises attaching the second textured surface of the glass layer to the photovoltaic devices using an encapsulation layer. In such methods, the diffusive layer can include at least one of titanium dioxide (TiO₂), polyethylene, polytetrafluoroethylene (PTFE), barium sulfate (BaSO₄), and white paint. In such methods, forming the diffusive layer can include using a shadow mask to mask the photovoltaic module and using a liquid diffuser to form the diffusive layer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a perspective view of an example of a photovoltaic module.

FIG. 1B shows an example of an enlarged perspective view of a portion of the photovoltaic module of FIG. 1A.

FIG. 2 shows a plan view of another example of a photovoltaic module.

FIG. 3A shows a cross-section of the photovoltaic module of FIG. 2 taken along the lines 3A-3A.

FIG. 3B shows a cross-section of the photovoltaic module of FIG. 2 taken along the lines 3B-3B.

FIGS. 4A-4B show scanning electron microscope (SEM) images of one example of a textured surface of a glass layer.

FIGS. 5A-5B show scanning electron microscope (SEM) images of another example of a textured surface of a glass layer.

FIG. 6 shows an example of a flow diagram illustration of a manufacturing process for a photovoltaic module.

### DETAILED DESCRIPTION

In some implementations, a photovoltaic module includes a plurality of photovoltaic devices and a glass layer disposed over the photovoltaic devices. The glass layer includes a first textured surface on a side of the glass layer opposite the photovoltaic devices. The first textured surface of the glass layer can diffract light incident the photovoltaic module, thereby increasing the efficiency of the photovoltaic module by increasing the path length of light through the photovoltaic devices and reducing the amount of light reflected off the photovoltaic module. For example, the first textured surface can include features configured to diffract light incident the photovoltaic module such that a portion of the light that reflects off of the photovoltaic devices and reaches the first textured surface of the glass layer can undergo total internal reflection (TIR) and be redirected back toward the photovoltaic devices. In some implementations, electrical conductors are disposed on the surface of the photovoltaic devices and a diffusive layer is provided over at least a portion of the electrical conductors so as to disperse light within the photovoltaic module. The diffusive layer can be applied to other structures of the photovoltaic module, including regions between photovoltaic devices. In some implementations, the glass layer further includes a second textured surface facing the photovoltaic devices for improving adhesion of the glass layer to the photovoltaic module when the photovoltaic module is encapsulated.

Implementations of the subject matter described in this disclosure can increase power efficiency of a photovoltaic module by, for a given amount of incident light, increasing the amount of light that reaches a photovoltaic device, thereby increasing the magnitude of a photocurrent generated from a given amount of light. Additionally, some implementations can increase the robustness of a photovoltaic module by improving the adhesion of a glass layer of a photovoltaic module to photovoltaic devices disposed therein. Furthermore, some implementations can be used to enhance light diffraction by providing diffractive features in the path of light incident on a photovoltaic module, thereby increasing the amount of light that undergoes TIR within the photovoltaic module and ultimately reaches a photovoltaic device.

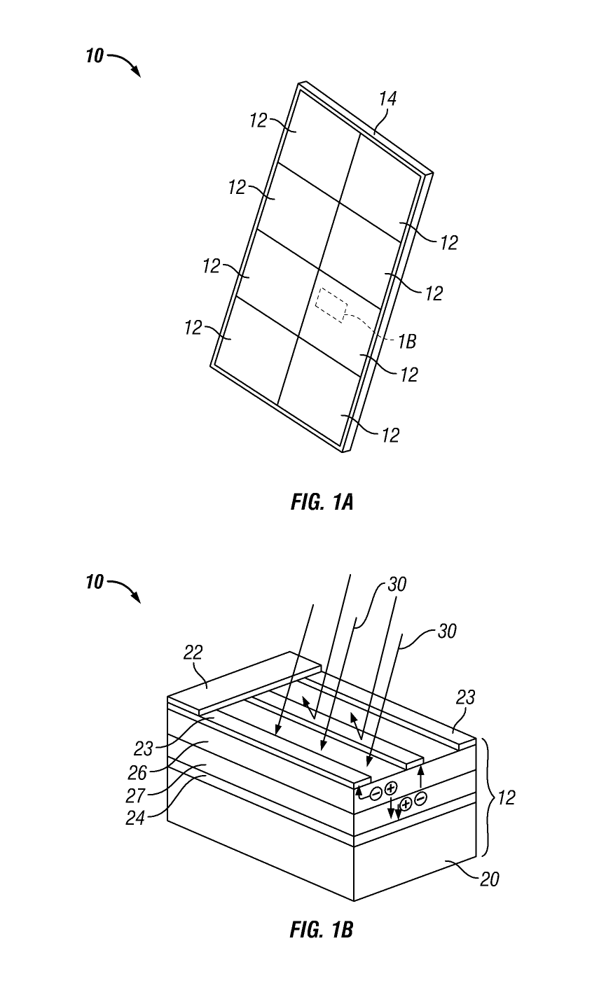

FIG. 1A shows a perspective view of an example of a photovoltaic module 10. The photovoltaic module 10 includes a plurality of photovoltaic devices 12 and a frame 14.

The photovoltaic module 10 can be used to convert light energy into electrical energy. For example, each of the photovoltaic devices 12 can be configured to convert light into a photocurrent that can be used to electrically power a load. The photovoltaic devices 12 can be any suitable photovoltaic device, including, for example, thin-film solar cells using silicon (Si), cadmium telluride (CdTe), and/or copper indium gallium (di)selenide (CIGS) technologies. Although the photovoltaic module 10 is illustrated as including eight photovoltaic devices 12, the photovoltaic module 10 can include any suitable number of photovoltaic devices, for example between about 4 and about 60 photovoltaic devices.

The photovoltaic module 10 can have a size selected based on a variety of factors, such as a size selected to achieve a desired power output for a particular lighting environment. In some implementations, the photovoltaic module 10 has a width in the range of about 30 cm to about 90 cm and a length in the range of about 30 cm to about 150 cm. The photovoltaic module 10 can be electrically coupled to other photovoltaic modules to form a photovoltaic array.

The frame 14 can provide structural support to the photovoltaic module 10. For example, the frame 14 can be used for housing the photovoltaic devices 12 and/or electrical conductors such as tabs or ribbons used for providing electrical connections between the photovoltaic devices 12. Additionally, the frame 14 can protect the photovoltaic module 10 from the environment, thereby improving the robustness of the photovoltaic module 10 and/or expanding the applications the photovoltaic module 10 can be used in. In some implementations, the frame 14 includes stainless steel and/or aluminum, including, for example, anodized aluminum, textured aluminum, and/or polished aluminum.

Although one configuration of the photovoltaic module 10 has been illustrated in FIG. 1A, other implementations are possible. For example, the photovoltaic module 10 can be configured to include more or fewer photovoltaic devices 12 and/or a different arrangement of the photovoltaic devices 12. Additionally, the photovoltaic module 10 can be modified to include additional structures, including, for example, conductors for electrical connections, mounting hardware, power conditioning equipment, and/or a battery for storing charge.

FIG. 1B shows an example of an enlarged perspective view of a portion of the photovoltaic module 10 taken in the box 1B of FIG. 1A. The illustrated portion of the photovoltaic module 10 includes a conductor 22 and a photovoltaic device 12. The photovoltaic device 12 includes secondary conductive lines 23 that are connected to conductor 22, which are sometimes referred to as “conductive fingers.” Photovoltaic module 10 also includes, an n-type layer 26, a p-type layer 27, a conductive layer 24, and a substrate 20.

The conductive layer 24 has been formed over the substrate 20, the p-type layer 27 has been formed over the conductive layer 24, the n-type layer 26 has been formed over the p-type layer 27, and the secondary conductive lines 23 have been formed over the n-type layer 26. The conductor 22 is disposed over the secondary conductive lines 23 and can be used to provide electrical connections between the secondary conductive lines 23 and/or to other structures of the photovoltaic module 10. In the illustrated configuration, the substrate 20 has been used to provide structural support to the photovoltaic device 12. In some implementations, the substrate 20 includes glass or plastic.

The photovoltaic device 12 includes the n-type layer 26 and the p-type layer 27, which can operate as a photodiode for converting light energy into electrical energy or current. For example, when the photovoltaic device 12 is illuminated with light 30, photons from the light can transfer energy to the photovoltaic device 12 and generate electron-hole pairs. For instance, photons having energy greater than the band-gap of the p-n junction formed from the p-type layer 27 and the n-type layer 26 can generate electron-hole pairs by band-to-band excitation and/or high-energy photons can generate electron-hole pairs by impact ionization or via recombination-generation centers within the lattice of the photovoltaic device 12. When photons create electron-hole pairs within or near the depletion region of the p-n junction of the photovoltaic device 12, the electric field of the depletion region can sweep the electrons to the secondary conductive lines 23 and holes to the conductive layer 24, thereby generating a photocurrent.

Although one example of the photovoltaic device 12 is illustrated in FIG. 1B, the photovoltaic device 12 can be any suitable photovoltaic structure. For example, the photovoltaic device 12 can be formed from a wide selection of light absorbing photovoltaic materials, including, for example, crystalline silicon (c-silicon), amorphous silicon (a-silicon), cadmium telluride (CdTe), copper indium diselenide (CIS), copper indium gallium diselenide (CIGS), III-V semiconductors, and/or organics such as light absorbing small molecular weight dyes and polymers. Furthermore, in some implementations the order of the n-type layer 26 and the p-type layer 27 can be reversed such that the n-type layer 26 is disposed over the conductive layer 24, the p-type layer 27 is disposed over the n-type layer 26, and the secondary conductive lines 23 are disposed over the p-type layer 27.

In some implementations, the conductive layer 24 can be a reflective layer, such as aluminum (Al) or silver (Ag). Accordingly, the conductive layer 24 can be configured to reflect light that passes through the photovoltaic device 12 back into the photovoltaic device 12, thereby increasing the efficiency of the photovoltaic module 10 by increasing the amount of the incident light 30 that is absorbed and converted into electrical current.

The secondary conductive lines 23 and the conductor 22 can be used to collect the photocurrent generated using the photovoltaic device 12. For example, a battery or load can be electrically coupled between the conductor 22 and the conductive layer 24, and electrons generated using the light 30 can reach the battery or load through the secondary conductive lines 23 and the conductor 22. Increasing the size and/or number of the secondary conductive lines 23 and the conductor 22 can reduce ohmic losses of the photovoltaic module 10, thereby reducing the amount of energy dissipated in the photovoltaic module as heat. However, increasing the surface area of the secondary conductive lines 23 and/or the conductor 22 can reduce the amount of light for photocurrent generation because portions of the light 30 incident on the photovoltaic module 10 can reflect off of the secondary conductive lines 23 and/or the conductor 22 and never the photovoltaic device 12.

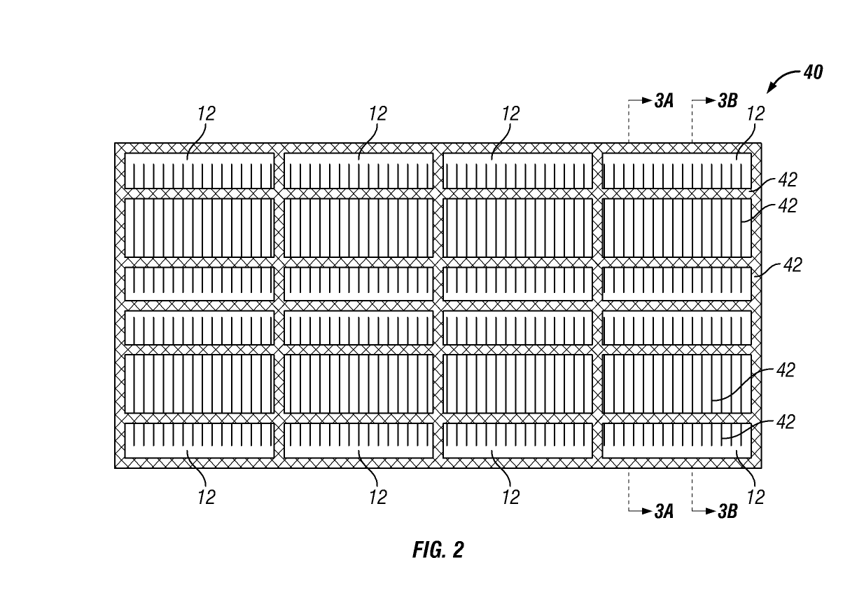

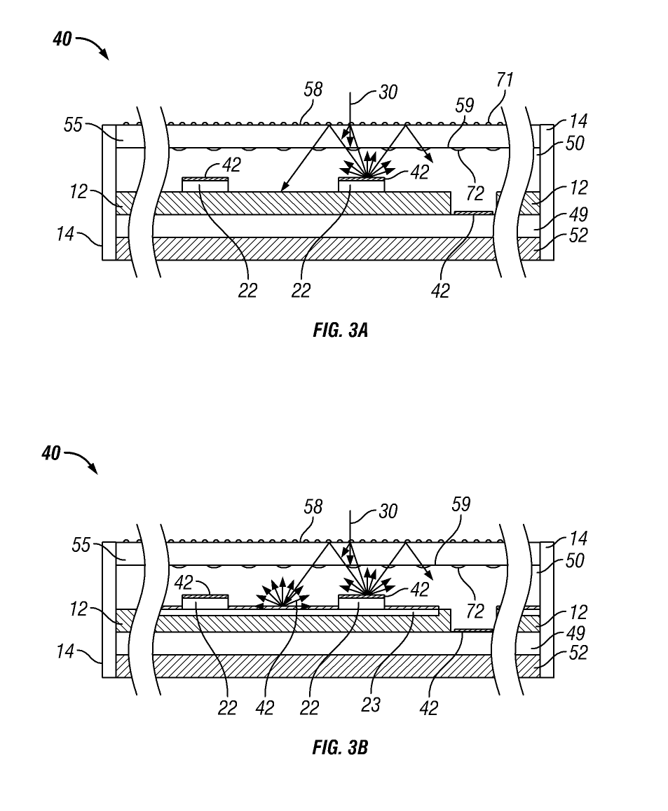

FIG. 2 shows a plan view of another example of a photovoltaic module 40. The photovoltaic module 40 includes a plurality of photovoltaic devices 12 and a diffusive layer (or material) 42. The diffusive layer 42 can be disposed over various portions of the photovoltaic module 40, including over conductors 22 disposed over the photovoltaic devices 12, over the secondary conductive lines 23 of the photovoltaic devices 12, and between the photovoltaic devices 12. Additional details of the diffusive layer 42 will be described below with reference to FIGS. 3A and 3B.

FIG. 3A shows a cross-section of the photovoltaic module 40 of FIG. 2 taken along the lines 3A-3A. The illustrated cross-section of the photovoltaic module 40 includes a glass layer 55, a first encapsulation layer 49, a second encapsulation layer 50, photovoltaic devices 12, conductors 22, the diffusive layer 42, a backsheet 52, and the frame 14.

To increase the amount of light absorbed by the photovoltaic devices 12, the glass layer 55 has been provided over the photovoltaic devices 12. The glass layer 55 includes a first textured surface 58 on a side of the glass layer 55 opposite the photovoltaic devices 12 and a second textured surface 59 opposite the first textured surface 58. The glass layer 55 can increase the efficiency of the photovoltaic module 40 by reducing the amount of light reflected off of the photovoltaic module 40. For example, the first textured surface 58 of the glass layer 55 can define a boundary for total internal reflection of light propagating within the photovoltaic module 40, and thus the glass layer 55 can be used to redirect a portion of light propagating in the photovoltaic module 40 back toward the photovoltaic devices 12.

In some implementations, the first textured surface 58 of the glass layer 55 includes features 71. The features 71 can be used to diffract light 30 that is incident upon the photovoltaic module 40, thereby helping to disperse light throughout the photovoltaic module 40. Since at least a portion of the diffracted light can have a longer path length through the photovoltaic devices 12 relative to light that is parallel to a surface normal of the photovoltaic devices 12, the diffracted light can have a greater chance of being absorbed by the photovoltaic devices 12 and converted into a photocurrent. Additionally, the features 71 can be used to redirect a portion of light incident the photovoltaic module to a relatively large angle of incidence with respect to the surface normal of the photovoltaic devices 12 such that light that reflects off of the photovoltaic devices 12 and reaches the first textured surface 58 of the glass layer 55 can undergo total internal reflection and be redirected back toward the photovoltaic devices 12.

In some implementations, the features 71 of the first surface 58 have a lateral dimension or width in the range of about 10 μm to about 100 μm. Although the first surface 58 is illustrated as having features 71 that are substantially evenly spaced apart, the features 71 on the textured surface need not be uniformly distributed. For example, the features 71 can be non-uniformly distributed on the first textured surface 58 to aid in reducing the cost of manufacturing the glass layer 55. The features 71 can have any suitable vertical dimension, such as a vertical dimension in the range of about 70 μm to about 200 μm. Although FIGS. 3A-3B illustrate a configuration in which the features 71 protrude from the glass layer 55, in certain implementations, the features 71 can extend into the first surface 58 of the glass layer 55.

To further improve the efficiency of the photovoltaic module 40, the diffusive layer 42 has been provided over various optically non-active portions of the photovoltaic module 40. For example, the diffusive layer 42 has been provided over the conductors 22 and between the photovoltaic devices 12.

Including the diffusive layer 42 over optically non-active portions of the photovoltaic module 40 that do not convert light into electrical energy can reduce the amount of reflected light that escapes the photovoltaic module 40. For example, by dispersing light that would otherwise be reflected and escape the photovoltaic module 40, a portion of the diffracted light can become totally internally reflected off the first textured surface 58 of the glass layer 55 one or more times before being absorbed by the photovoltaic devices 12. Accordingly, including the diffusive layer 42 can improve the efficiency of photovoltaic module 40 relative to a photovoltaic module that omits the diffusive layer 42.

In some implementations, such as in the configuration illustrated in FIG. 3A, a photovoltaic module 40 can include both the diffusive layer 42 and the glass layer 55 having the features 71 for diffusing light. Simulations and experimental data have shown that including both the diffusive layer 42 and the glass layer 55 in a photovoltaic module can generate an improvement in solar efficiency that is additive. For example, one simulation demonstrated that while including either the diffusive layer 42 or the glass layer 55 individually in a photovoltaic module 40 improved efficiency by about 3.5%, including both the diffusive layer 42 and the glass layer 55 in the photovoltaic module 40 improved efficiency by about 7%. Thus, rather than interfering with one another, the diffusive layer 42 and the glass layer 55 can each provide an additive contribution to the efficiency of the photovoltaic module 40, thereby providing a greater efficiency improvement than might otherwise be expected.

The diffusive layer 42 can be, for example, a Lambertian diffuser that diffuses light over a relatively wide range of angles such that the light has about the same brightness for each angle of reflection. In some implementations, the diffusive layer 42 has a thickness of less than about 0.5 μm. The diffusive layer 42 can include, for example, titanium dioxide (TiO₂), polyethylene (including high density polyethylene), polytetrafluoroethylene (PTFE), barium sulfate (BaSO₄), and/or white paint. In some implementations, the diffusive layer 42 includes a film. Such films can be manually applied or applied using an automated process. The diffusive layer 42 need not be a film. For example, in some implementations, including any of the implementations described and illustrated herein, the diffusive layer 42 can be a paste, a powder, a paint or other mixture having particles suspended in a liquid or gel base material, and/or a liquid (as applied) that dries or hardens forming the diffusive layer 42. material. Such diffusive material can be suitably applied using spray techniques, automatic or manual coating techniques, or other suitable coating techniques.

The illustrated glass layer 55 also includes the second textured surface 59, which can aid in improving the adhesion of the glass layer 55 to the second encapsulation layer 50 when the photovoltaic module 40 is assembled. For example, the second textured surface 59 can include the features 72 for increasing the surface area of the second textured surface 59, thereby helping the second encapsulation layer 50 to bind to the glass layer 55. In some implementations, the second encapsulation layer 50 can be a polymer layer such as ethylene-vinyl acetate (EVA), and the second encapsulation layer 50 can be melted during formation of the photovoltaic module 40 to attach the glass layer 55 to the photovoltaic devices 12. Although the illustrated glass layer 55 includes the second textured surface 59, the glass layer 50 need not include the second textured surface 59. Accordingly, in some implementations, the glass layer 55 includes a textured surface 58 opposite the photovoltaic devices 12 and a smooth surface opposite the textured surface 58.

In some implementations, the features 72 of the second textured surface 59 have a lateral dimension or width in the range of about 1 mm to about 10 mm. Accordingly, in some configurations the features 72 of the second textured surface 59 are larger than the features 71 of the first textured surface 58. Although the first surface 58 is illustrated as having features that are substantially evenly spaced apart, the features 72 of the second textured surface 59 need not be uniformly distributed. For example, the features 72 can be randomly distributed on the second textured surface 59 to aid in reducing the cost of manufacturing the glass layer 55. The features 72 can have any suitable vertical dimension, such as a vertical dimension in the range of about 0.5 μm to about 20 μm. Although FIGS. 3A-3B illustrate a configuration in which the features 72 protrude from the glass layer 55, in certain implementations, the features 72 can extend into the second surface 59 of the glass layer 55.

The illustrated photovoltaic module 40 can be formed using any suitable manufacturing process. For example, the first encapsulation layer 49 can be provided over the backsheet 52 and the photovoltaic devices 12 can be provided over the first encapsulation layer 49. In some implementations, the first encapsulation layer 49 includes ethylene-vinyl acetate (EVA) that is heated to bind the backsheet 52 to the photovoltaic devices 12. Furthermore, the conductors 22 can be provided over the photovoltaic devices 12, such as by using a conductive epoxy. In some implementations, the diffusive layer 42 can be provided over the conductors 22 and between the photovoltaic devices 12 after the conductors 22 are attached to the photovoltaic devices 12. However, in other implementations, the diffusive layer 42 can be provided over the conductors 22 before the conductors 22 are provided over the photovoltaic devices 12. The second encapsulation layer 50 can be provided over the photovoltaic devices 12, and the glass layer 55 can be provided over the second encapsulation layer 50. The second encapsulation layer 50 can include ethylene-vinyl acetate (EVA) that is heated to bind the photovoltaic devices 12 to the glass layer 55. In some implementations, the frame 14 can be provided after the glass layer 55 is attached to the photovoltaic devices 12. However, the frame 14 can be attached to the photovoltaic module at other times. For example, the frame 14 can be attached to the backsheet 52 before providing the photovoltaic devices 12.

In some implementations at least a portion of the diffusive layer 42 is applied using a screen printing process. For example, before the second encapsulation layer 50 is provided over the photovoltaic devices 12, a roller can be moved over the partially fabricated photovoltaic module 40 and used to provide a liquid diffuser in certain portions of the photovoltaic module 40, such as portions of the photovoltaic module 40 that are exposed by a shadow mask. In some implementations, the liquid diffuser can include, for example, titanium dioxide (TiO₂). Employing a screen printing process can aid in reducing the cost of applying the diffusive layer 42 and/or can permit the diffusive layer 42 to be applied over relatively small features of the photovoltaic module 40. Although the diffusive layer 42 can be applied using screen printing, the diffusive layer 42 can be applied in all or in part using other techniques. For example, the diffusive layer 42 can be formed from a sheet that is cut to form a desired pattern and attached to the partially fabricated photovoltaic module 40 using an adhesive.

FIG. 3B shows a cross-section of the photovoltaic module of FIG. 2 taken along the lines 3B-3B. The illustrated cross-section of the photovoltaic module 40 includes the glass layer 55, the first encapsulation layer 49, the second encapsulation layer 50, the photovoltaic devices 12, the conductors 22, the diffusive layer 42, the backsheet 52, the frame 14, and the secondary conductive lines 23.

In the configuration illustrated in FIG. 3B, the diffusive layer 42 has been provided over the conductors 22, between the photovoltaic devices 12, and over the secondary conductive lines 23. By including the diffusive layer 42 over the secondary conductive lines 23 of the photovoltaic devices 12, the amount of light that is reflected off the photovoltaic module 40 can be reduced. For example, the diffusive layer 42 can be configured to diffuse a portion of light, that would otherwise be reflected and not enter the photovoltaic devices 12, such that the light is redirected to an angle suitable for total internal reflection within the photovoltaic module 40. Accordingly, including the diffusive layer 42 can reduce the amount of light that escapes the photovoltaic module 40 through the glass layer 55 relative to a scheme in which the diffusive layer 42 is not included over the secondary conductive lines 23. In some implementations, the diffusive layer 42 is formed over the secondary conductive lines 23 during manufacture of the photovoltaic devices 12.

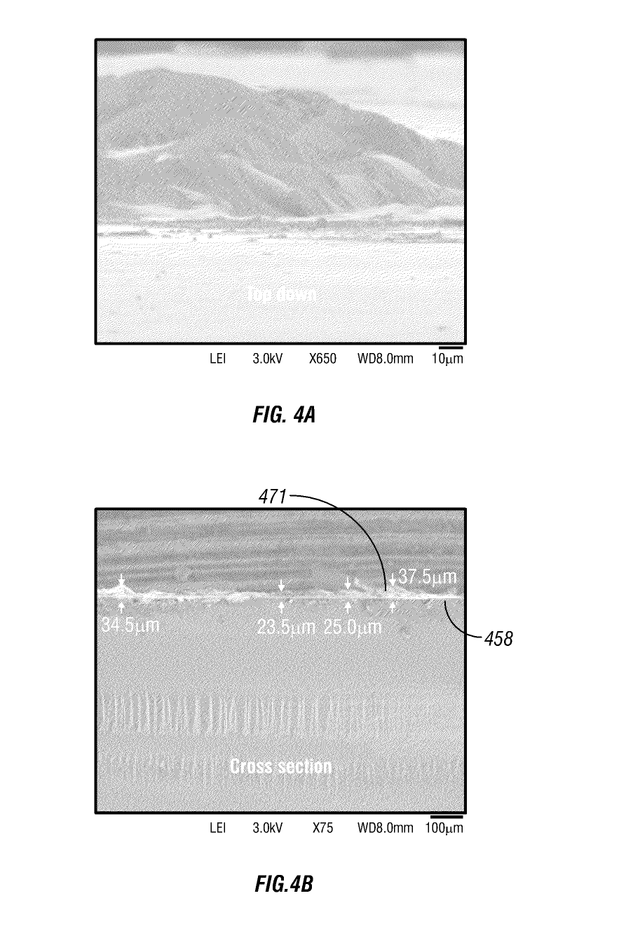

FIGS. 4A-4B show scanning electron microscope (SEM) images of one example of a textured surface of a glass layer. FIG. 4A shows a top down SEM image of the textured surface of the glass layer and FIG. 4B shows a cross-section of the textured surface of the glass layer. In the illustrated configuration, the textured surface 458 includes features 471 that have a width smaller that about 37.5 μm and that are randomly arranged. The textured surface can be used as, for example, the first textured surface 58 of FIGS. 3A-3B. However, the first textured surface 58 of FIGS. 3A-3B can be formed in other ways, including using features of different sizes and/or features arranged in a different pattern.

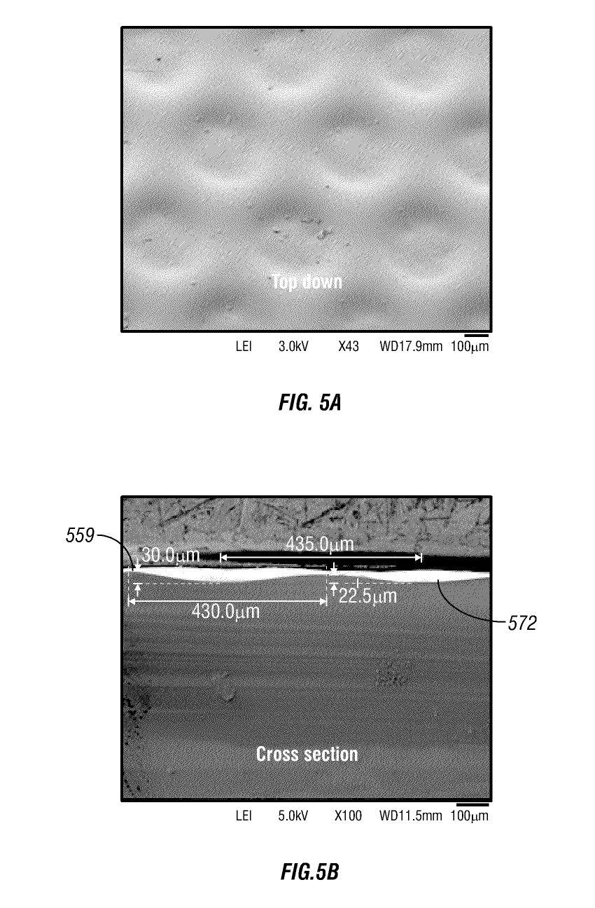

FIGS. 5A-5B show scanning electron microscope (SEM) images of another example of a textured surface of a glass layer. FIG. 5A shows a top down SEM image of the textured surface of the glass layer and FIG. 5B shows a cross-section of the textured surface of the glass layer. In the illustrated configuration, the textured surface 559 includes features 572 that have a width smaller than about 430 μm that are uniformly arranged. The textured surface can be used as, for example, the second textured surface 59 of FIGS. 3A-3B. However, the second textured surface 59 of FIGS. 3A-3B can be formed in other ways, including using features of different sizes and/or features arranged in a different pattern.

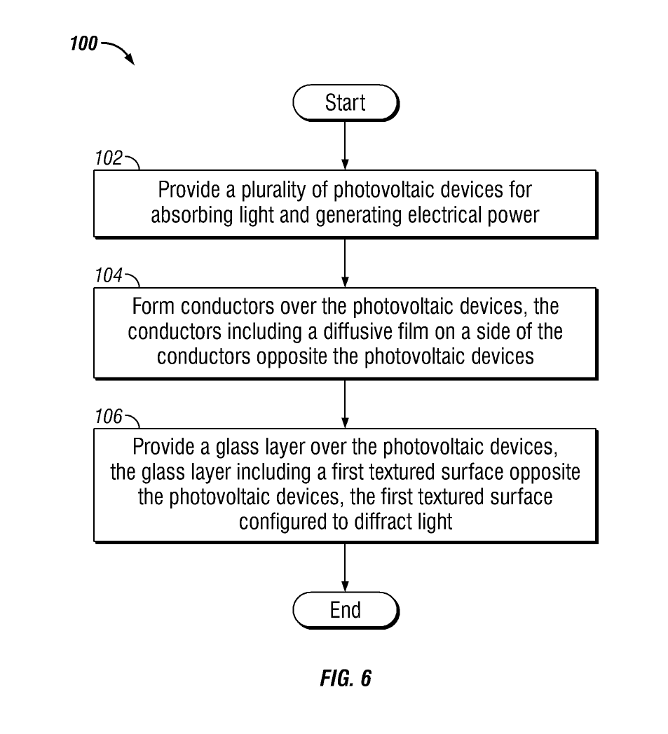

FIG. 6 shows an example of a flow diagram illustration of a manufacturing process 100 for a photovoltaic module.

In block 102, a plurality of photovoltaic devices for absorbing light and generating electrical power are provided. For example, a plurality of thin-film photovoltaic devices, such as thin-film solar cells using silicon (Si), cadmium telluride (CdTe), and/or copper indium gallium (di)selenide (CIGS) technologies can be arranged in an array. Although the process 100 is illustrated as starting at block 102, the process 100 can include additional steps before providing the plurality of photovoltaic devices. For example, a backsheet and an encapsulation layer can be provided before providing the photovoltaic devices.

In some implementations, at least a portion of the photovoltaic devices are covered with a diffusive layer. For example, the photovoltaic devices can include conductive lines that are disposed on the photovoltaic material (e.g., secondary conductive lines 23 FIG. 3B) that are coated with a diffusive layer, such as a titanium dioxide (TiO₂) layer.

The process 100 illustrated in FIG. 6 continues at block 104, in which conductors are formed over the photovoltaic devices. The conductors include a diffusive layer on a side of the conductors opposite the photovoltaic devices. The diffusive layer can aid in diffracting light within the photovoltaic module, thereby increasing a path length of light through the photovoltaic devices and increasing the probability that the photovoltaic devices absorb the light and convert the light to a photocurrent. The diffusive layer can also redirect light to an angle suitable for total internal reflection (TIR) within the photovoltaic module. In some implementations, the diffusive layer includes titanium dioxide (TiO₂). The diffusive layer can be provided on the conductors using any suitable process. For example, the diffusive layer can be provided using a screen printing process, or sheets of the diffusive layer can be cut into a desired pattern and attached to the photovoltaic module using any suitable adhesive. In some implementations, the diffusive layer is also provided between the photovoltaic devices.

The conductors can aid in providing electrical connections within each photovoltaic device and between the photovoltaic devices. For example, in some implementations tabs or ribbons (not shown) are provided to electrically connect conductors disposed on different photovoltaic devices. In certain implementations, the surfaces of such tabs or ribbons that are exposed to incident light can also be coated with a diffusive layer, such as by spray coating the tabs or ribbons before attaching them to the conductors.

In a block 106, a glass layer is provided over the photovoltaic devices. The glass layer includes a first textured surface opposite the photovoltaic devices, and the first textured surface is configured to diffract light. For example, the first textured surface can include features having a lateral dimension or width of about 10 μm to about 100 μm. The features can be arranged in any suitable pattern, including, for example, uniform or non-uniform patterns.

In some implementations, an encapsulation layer, such as an ethylene-vinyl acetate (EVA) layer is provided over the photovoltaic devices and conductors before the glass layer is provided. The encapsulation layer can aid in attaching the glass layer to the photovoltaic devices, thereby improving the physical integrity of the photovoltaic module. In some implementations, the glass layer includes a second textured surface facing the photovoltaic devices, and the second textured surface is configured to improve the adhesion of the encapsulation layer to the glass layer. For example, the second textured surface can include features having a lateral dimension or width of about 1 mm to about 10 mm to help the encapsulation layer bind to the glass layer. However, in some implementations, the glass layer includes a smooth surface facing the photovoltaic devices to reduce the manufacturing cost of the photovoltaic module.

Although FIG. 6 illustrates one example of a manufacturing process for a photovoltaic module, other configurations are possible. For example, many additional steps may be employed before, in the middle of, or after the illustrated sequence, but such steps are omitted here for clarity of the description.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that any described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A photovoltaic module comprising:
a plurality of photovoltaic devices configured to absorb light and generate electrical power;
a plurality of conductors disposed over the plurality of photovoltaic devices and configured to provide electrical connectivity within the photovoltaic module;
a glass layer disposed over the plurality of conductors and the photovoltaic devices, the glass layer including a first textured surface opposite the plurality of photovoltaic devices, wherein the first textured surface includes a plurality of features configured to diffract light incident the photovoltaic module; and
a diffusive layer disposed over at least a portion of the plurality of conductors, the diffusive layer configured to diffract light.

2. The photovoltaic module of claim 1, wherein each of the plurality of features of the first textured surface has a width in the range of about 10 μm to about 100 μm.

3. The photovoltaic module of claim 1, wherein the photovoltaic module further includes an encapsulation layer disposed between the glass layer and the plurality of photovoltaic devices, and wherein the glass layer further includes a second textured surface opposite the first textured surface, the second textured surface including a plurality of features configured to improve the adhesion of the encapsulation layer to the glass layer.

4. The photovoltaic module of claim 3, wherein a feature width of the second textured surface is greater than a feature width of the first textured surface.

5. The photovoltaic module of claim 4, and wherein each of the plurality of features of the second textured surface has a width in the range of about 1 mm to about 10 mm.

6. The photovoltaic module of claim 1, wherein the diffusive layer includes at least one of titanium dioxide (TiO₂), polyethylene, polytetrafluoroethylene (PTFE), barium sulfate (BaSO₄), and white paint.

7. The photovoltaic module of claim 1, wherein the diffusive layer is further disposed between the plurality of photovoltaic devices.

8. The photovoltaic module of claim 1, wherein the plurality of conductors includes a plurality of secondary conductive lines for collecting a photocurrent generated by the plurality of photovoltaic devices, wherein the diffusive layer is disposed over at least a portion of the plurality of secondary conductive lines.

9. The photovoltaic module of claim 1, wherein the diffusive layer is a Lambertian diffuser.

10. The photovoltaic module of claim 1, wherein the diffusive layer includes a film.

11. The photovoltaic module of claim 1, wherein the plurality of features of the first textured surface are arranged in a non-uniform pattern.

12. A photovoltaic module comprising:
a plurality of photovoltaic devices configured to absorb light and generate electrical power;
a plurality of conductors disposed over the plurality of photovoltaic devices and configured to provide electrical connectivity within the photovoltaic module; and
a means for diffusing light disposed over at least a portion of the plurality of conductors.

13. The photovoltaic module of claim 12, further comprising a glass layer disposed over the plurality of conductors and the photovoltaic devices, the glass layer including a first textured surface opposite the plurality of photovoltaic devices, wherein the first textured surface includes a plurality of features configured to diffract light incident on the plurality of features.

14. The photovoltaic module of claim 13, wherein each of the plurality of features of the first textured surface has a width in the range of about 10 μm to about 100 μm.

15. The photovoltaic module of claim 14, wherein the photovoltaic module further includes an encapsulation layer disposed between the glass layer and the plurality of photovoltaic devices, and wherein the glass layer further includes a second textured surface opposite the first textured surface, the second textured surface including a plurality of features configured to improve the adhesion of the encapsulation layer to the glass layer.

16. The photovoltaic module of claim 15, wherein each of the plurality of features of the first textured surface has a width in the range of about 1 mm to about 10 mm.

17. The photovoltaic module of claim 12, wherein at least a portion of the diffusive layer is applied between the photovoltaic devices.

18. The photovoltaic module of claim 12, wherein the diffusive layer includes at least one of titanium dioxide (TiO₂), polyethylene, polytetrafluoroethylene (PTFE), barium sulfate (BaSO₄), and white paint.

19. A method of manufacturing a photovoltaic module, the method comprising:
providing a plurality of photovoltaic devices configured to absorb light and generate electrical power;
forming a plurality of conductors over the plurality of photovoltaic devices;
providing a glass layer over the photovoltaic devices, the glass layer including a first textured surface opposite the plurality of photovoltaic devices; and
forming a diffusive layer over at least a portion of the plurality of conductors, the diffusive layer configured to diffract light.

20. The method of claim 19, wherein the glass layer further includes a second textured surface opposite the first textured surface, and wherein the method further comprises attaching the second textured surface of the glass layer to the photovoltaic devices using an encapsulation layer.

21. The method of claim 19, wherein the diffusive layer includes at least one of titanium dioxide (TiO₂), polyethylene, polytetrafluoroethylene (PTFE), barium sulfate (BaSO₄), and white paint.

22. The method of claim 19, further comprising forming the diffusive layer between the plurality of photovoltaic devices.

23. The method of claim 19, wherein forming the diffusive layer includes using a shadow mask to mask the photovoltaic module and using a liquid diffuser to form the diffusive layer.
